(19) United States
(12) Patent Application Publication
(10) Pub. No.: US 2013/0126996 A1
(43) Pub. Date: May 23, 2013

(54) MAGNETIC MEMORY DEVICE

(71) Applicant: Dae-eun Jeong, Yongin-si (KR)

(72) Inventor: Dae-eun Jeong, Yongin-si (KR)

(21) Appl. No.: 13/549,427

(22) Filed: Jul. 14, 2012

(30) Foreign Application Priority Data
Nov. 21, 2011 (KR) 10-2011-0121731

(51) Int. Cl. H01L 29/82

(52) U.S. Cl. 257/421; 257/E29.323

(57) ABSTRACT

A magnetic memory device using magnetic resistance is provided. The magnetic memory device may include a magnetic memory layer comprising a plurality of magnetic layers; and a tunnel barrier layer provided between the plurality of magnetic layers; and a stress-generating layer for applying stress to the tunnel barrier layer.

### CROSS-REFERENCE TO RELATED APPLICATIONS

This application claims the benefit of Korean Patent Application No. 10-2011-0121731 filed on Nov. 21, 2011, in the Korean Intellectual Property Office, the disclosure of which is incorporated herein in its entirety by reference.

### BACKGROUND

The inventive concept relates to a memory device, and more particularly, to a magnetic memory device using magnetic resistance.

Semiconductor products require high-capacity data processing capabilities while their size is being gradually reduced. There is further demand to increase the operation speed and integration density of memory devices used for electronic products. To meet these requirements, magnetic memory devices, such as a magnetic random access memory (MRAM), are being developed, which perform a memory function by using a change in resistance according to a change in polarity of a magnetic body. Recently, studies on spin-transfer torque MRAM (STT-MRAM) using spin polarization are actively being performed.

### SUMMARY

According to an aspect of the inventive concepts, a magnetic memory device is provided, which may include: a magnetic memory layer comprising a plurality of magnetic layers, a tunnel barrier layer arranged between the plurality of magnetic layers, and a stress generating layer configured to apply stress to the tunnel barrier layer.

In some embodiments of the inventive concepts, the magnetic memory device may further include a plurality of electrodes disposed at opposite sides of the magnetic memory layer, wherein the stress-generating layer may generate stress according to a voltage applied by the plurality of electrodes.

In some further embodiments of the inventive concepts, the stress generated by the stress-generating layer may be tensile stress.

In still further embodiments of the inventive concepts, the stress-generating layer may have a piezoelectric deformation characteristic.

In additional embodiments of the inventive concepts, the stress-generating layer may have a magnetostrictive characteristic.

In other embodiments of the inventive concepts, the stress generating layer may be disposed between any one or more of the plurality of electrodes and the magnetic memory layer.

In yet other embodiments of the inventive concepts, the stress-generating layer may include a plurality of stress generating layers.

In still other embodiments of the inventive concepts, the plurality of stress generating layers may be disposed at opposite sides of the magnetic memory layer.

In some embodiments of the inventive concepts, the stress-generating layer may form an integral, single-body structure with at least one of the plurality of magnetic layers.

In some embodiments of the inventive concepts, the stress-generating layer may have a magnetic characteristic.

In some further embodiments of the inventive concepts, the stress-generating layer may include at least one of a ferroelectric material, a giant magnetostrictive material, and a multi-layered superlattice structural material.

In some embodiments of the inventive concepts, the stress generating layer may have a cross-sectional area that is the same as or larger than that of the tunnel barrier layer.

According to another aspect of the inventive concepts, a magnetic memory device is provided, which may include: a magnetic memory layer including a plurality of magnetic layers and a tunnel barrier layer provided between the plurality of magnetic layers; a plurality of electrodes disposed at opposite sides of the magnetic memory layer; an auxiliary electrode disposed at a side of the magnetic memory layer opposite at least any one of the plurality of electrodes; and a stress generating layer disposed between the at least any one of the plurality of electrodes and the auxiliary electrode, where the stress generating layer is configured to generate stress according to a voltage applied between the at least any one of the plurality of electrodes and the auxiliary electrode.

In some embodiments of the inventive concepts, the auxiliary electrode may have a potential difference from the at least any one of the plurality of electrodes so as to generate the stress in the stress generating layer.

In some embodiments of the inventive concepts, the at least any one of the plurality of electrodes may be electrically connected to the auxiliary electrode.

According to yet another aspect of the inventive concepts, a magnetic memory device is provided, which may include: a magnetic memory layer comprising a plurality of magnetic layers; a tunnel barrier layer provided between the plurality of magnetic layers; and a stress generating layer configured to apply stress to the tunnel barrier layer, wherein the stress generating layer may include a giant magnetostrictive material. The giant magnetostrictive material may have a [AₓB_{y}], structural formula, where “A” denotes at least one of Gd, Tb, Sm, Dy, and Mo and “B” denotes at least one of Fe, Co, and Ni.

### BRIEF DESCRIPTION OF THE DRAWINGS

Exemplary embodiments of the inventive concept will be more clearly understood from the following detailed description taken in conjunction with the accompanying drawings in which:

FIG. 1 schematically illustrates a magnetic memory array according to an exemplary embodiment of the present inventive concept;

FIG. 2 is a somewhat schematic cross-sectional view illustrating a magnetic memory device in an area II of the memory array of FIG. 1, according to an exemplary embodiment of the present inventive concepts;

FIGS. 3 to 6 are schematic depictions of magnetic memory elements for explaining a method of storing data using a magnetization direction of the magnetic memory layer of FIG. 2;

FIG. 7 provides a schematic depiction comparing magnetic memory structures without and including a stress generating layer for explaining a function of a stress generating layer according to an exemplary embodiment of the present inventive concepts;

FIGS. 8 and 9 are somewhat schematic cross-sectional views illustrating magnetic memory devices in the area II of the memory array of FIG. 1, according to other exemplary embodiments of the present inventive concepts;

FIGS. 10 to 12 are somewhat schematic cross-sectional views illustrating magnetic memory devices in the area II of the memory array of FIG. 1, according to other exemplary embodiments of the present inventive concepts;

FIGS. 13 to 15 are somewhat schematic cross-sectional views illustrating magnetic memory devices in the area II of the memory array of FIG. 1, according to other exemplary embodiments of the present inventive concepts;

FIG. 16 is a somewhat schematic cross-sectional view illustrating a DRAM device including a stress generating layer, according to another exemplary embodiment of the present inventive concepts;

FIG. 17 is a schematic block diagram illustrating a memory card according to another exemplary embodiment of the present inventive concepts;

FIG. 18 is a schematic block diagram illustrating a system according to an exemplary embodiment of the present inventive concepts; and

FIG. 19 is a perspective view of an electronic apparatus illustrating an example of a device to which a semiconductor device manufactured according to the present inventive concepts may be applied.

### DETAILED DESCRIPTION OF THE EMBODIMENTS

Reference will now be made in detail to exemplary embodiments of the present inventive concepts, examples of which are illustrated in the accompanying drawings. It should be noted, however, that the inventive concepts are not limited to the exemplary embodiments illustrated hereinafter, and that the embodiments herein are introduced only to provide an easy and more complete understanding of the scope and spirit of the inventive concepts. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein should therefore be interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but should be interpreted to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature only and their shapes may not be intended to illustrate the actual shape of a region of a device and are therefore not intended to limit the scope of exemplary embodiments, unless explicitly stated otherwise.

Unless otherwise defined, all terms (including technical and scientific terms) used herein have the same meaning as commonly understood by one of ordinary skill in the art to which these exemplary embodiments belong. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

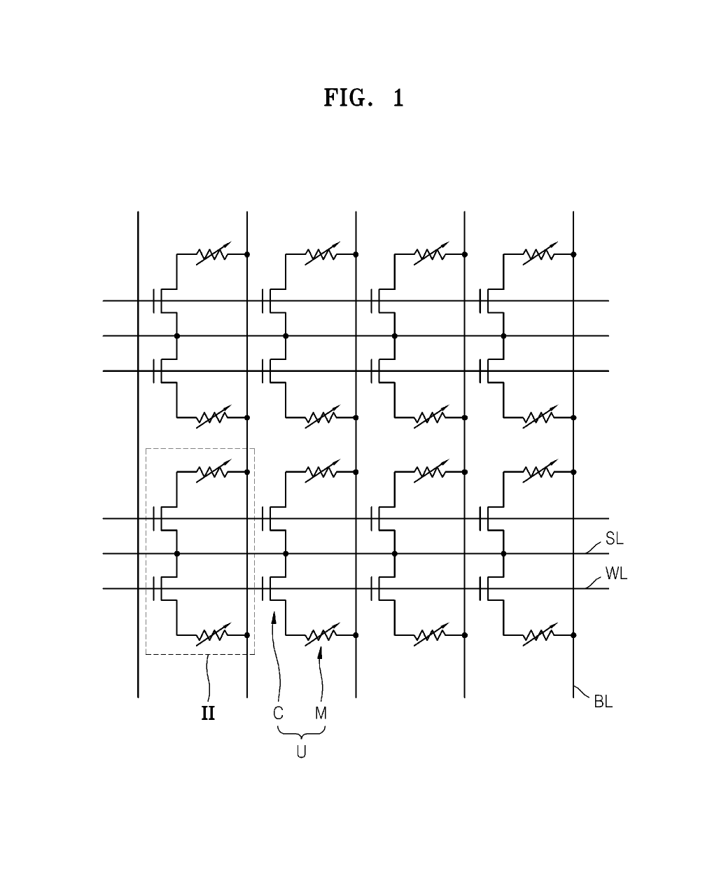

FIG. 1 schematically illustrates a magnetic memory array according to an exemplary embodiment of the present inventive concept.

Referring to FIG. 1, a magnetic memory device includes a plurality of unit cells U of a magnetic memory device arranged in a matrix form. Each of the unit cells U of a magnetic memory device can include an access portion C and a memory portion M. The unit cells U of a magnetic memory device are electrically connected to a word line WL and a bit line BL. Also, when the access portion C is a transistor as illustrated in FIG. 1, the unit cell U of a magnetic memory device may further include a source line SL that is electrically connected to a source area of the access portion C. The word line WL and the bit line BL may be arranged at a certain angle, for example, at a right angle, in two dimensions. Alternatively, the word line WL and the bit line BL may be arranged to be parallel to each other or at another desired orientation with respect to each other. The source line SL may be a common source line with respect to the unit cells U of a magnetic memory device.

The access portion C controls supply of current to the memory portion M according to a voltage of the word line WL. The access portion C may be a MOS transistor, a bipolar transistor, or a diode, for example.

The memory portion M may include a magnetic material or a magnetic tunnel junction (MTJ). Also, the memory portion M may perform a memory function by using a spin transfer torque (STT) phenomenon, such that a magnetization direction of a magnetic body is changed according to an input current.

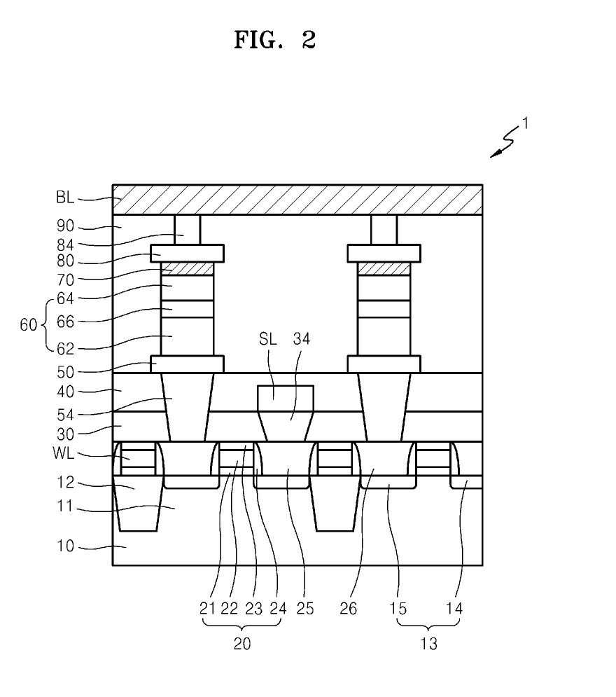

FIG. 2 is a somewhat schematic cross-sectional view illustrating a magnetic memory device 1 in an area II of the memory array of FIG. 1, according to an exemplary embodiment of the present inventive concepts.

Referring to FIG. 2, the magnetic memory device 1 can include a substrate 10, a gate structure 20 formed on the substrate 10, a magnetic memory layer 60 electrically connected to the gate structure 20 and configured to perform a memory function by magnetoresistance, and a lower electrode 50 and an upper electrode 80 disposed at opposite ends of the magnetic memory layer 60. The gate structure 20 may correspond to the access portion C of FIG. 1. The magnetic memory layer 60 may correspond to the memory portion M of FIG. 1. The magnetic memory device 1 may further include a stress-generating layer 70 disposed between the lower electrode 50 and the upper electrode 80. The stress-generating layer 70 can be configured to transfer stress generated by the lower and upper electrodes 50 and 80 to the magnetic memory layer 60. In the present exemplary embodiment, the stress-generating layer 70 can be disposed between the magnetic memory layer 60 and the upper electrode 80.

The substrate 10 may, for instance, include a semiconductor layer including silicon (Si), silicon-germanium (SiGe), and/or silicon carbide (SiC), a conductive layer including titanium (Ti), titanium nitride (TiN), aluminium (Al), tantalum (Ta), tantalum nitride (TaN), and/or tantalum aluminium nitride (TaA1N), or a dielectric layer including silicon oxide, titanium oxide, aluminium oxide, zirconium oxide, or hafnium oxide. Also, the substrate 10 may include an epitaxial layer, a silicon-on-insulator (SOI) layer, and/or a semiconductor-on-insulator (SEOI) layer. Also, although not illustrated, the substrate 10 may further include a conductive line, such as a word line or a bit line, and may include other semiconductor devices.

The substrate 10 can include an isolation layer 12 for defining an active region 11. The isolation layer 12 may be formed by a typical shallow trench isolation (STI) method. The active region 11 may include an impurity region 13. The impurity region 13 may further include a low-concentration impurity region (not illustrated) close to the gate structure 20 and a high-concentration impurity region (not illustrated) separated from the gate structure 20. The impurity region 13 may include a source region 14 and a drain region 15.

The gate structure 20 can be disposed over the active region 11 of the substrate 10. The gate structure 20 may include a gate insulation layer 21, a gate electrode layer 22, a capping layer 23, and a spacer 24. The gate electrode layer 22 may provide the word line WL of FIG. 1. The gate structure 20, the source region 14, and the drain region 15 may provide a MOS transistor to function as an access device. Also, the gate structure 20 may not be restricted to the MOS transistor and may be a bipolar transistor or a diode.

A first contact plug 25 and a second contact plug 26 having conductivity may be disposed outside the gate structure 20. The first contact plug 25 may be electrically connected to the source region 14. The second contact plug 26 may be electrically connected to the drain region 15. The first and second contact plugs 25 and 26 may include a conductive material, for example, at least one of titanium (Ti), titanium nitride (TiN), tungsten (W), and tungsten nitride (WN). The first and second contact plugs 25 and 26 may have a stacked structure of the above-described materials. In FIG. 2, although the first and second contact plugs 25 and 26 are illustrated as being arranged in a self-aligned manner using the spacer 24 of the gate structure 20, the present inventive concept is not limited thereto. That is, the first and second contact plugs 25 and 26 may be formed by partially removing an area between the neighboring gate structures 20 and filling a conductive material therein.

A first interlayer insulation layer 30 and a second interlayer insulation layer 40 covering the gate structure 20 can be sequentially disposed above the substrate 10. The first and second interlayer insulation layers 30 and 40 may include oxide, nitride, and oxynitride, such as for example, at least one of silicon oxide, silicon nitride, and silicon oxynitride. The first and second interlayer insulation layers 30 and 40 may be the same material or different materials. Alternatively, the first and second interlayer insulation layer 30 and 40 may include organic materials such as carbon.

A third contact plug 34 can be disposed in the first interlayer insulation layer 30. The third contact plug 34 may be electrically connected to the first contact plug 25 by passing through the first interlayer insulation layer 30. Also, a source line SL can be disposed on the first interlayer insulation layer 30 and electrically connected to the third contact plug 34. Accordingly, the source region 14 and the source line SL can be electrically connected to each other through the third contact plug 34 and the first contact plug 25. The third contact plug 34 may include a conductive material, such as for example, at least one of titanium (Ti), titanium nitride (TiN), tungsten (W), and tungsten nitride (WN). Also, the third contact plug 34 may have a stack structure of the above-described materials. The source line SL may be a common source line.

A fourth contact plug 54 can be disposed in the first and second interlayer insulation layers 30 and 40. The fourth contact plug 54 may be electrically connected to the second contact plug 26 by passing through the first and second interlayer insulation layers 30 and 40. Also, the lower electrode 50 may be disposed on the second interlayer insulation layer 40 and electrically connected to the fourth contact plug 54. Accordingly, the drain region 15 and the lower electrode 50 can be electrically connected to each other by the fourth contact plug 54 and the second contact plug 26. The fourth contact plug 54 may include a conductive material, such as at least one of titanium (Ti), titanium nitride (TiN), tungsten (W), and tungsten nitride (WN). Also, the fourth contact plug 54 may have a stack structure of the above-described materials.

Still referring to FIG. 2, although the first and second interlayer insulation layers 30 and 40 are illustrated as being separated from each other, the present inventive concept is not limited thereto. That is, the first and second interlayer insulation layers 30 and 40 may be a single layer. In that case, the source line SL and the lower electrode 50 may be configured without a step-shaped configuration. That is, the source line SL and the lower electrode 50 may be disposed on the same interlayer insulation layer.

The lower electrode 50 may be formed by a typical etch method, a damascene method, or a dual damascene method, for example. The lower electrode 50 may include metal such as aluminium (Al), copper (Cu), tungsten (W), titanium (Ti), or tantalum (Ta), or an alloy such as titanium tungsten (TiW) or titanium aluminium (TiAl), or carbon (C). Also, the lower electrode 50 may include titanium nitride (TiN), titanium aluminium nitride (TiAlN), tantalum nitride (TaN), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminium nitride (ZrAlN), molybdenum aluminium nitride (MoAlN), tantalum silicon nitride (TaSiN), tantalum aluminium nitride (TaAlN), titanium oxynitride (TiON), titanium aluminium oxynitride (TiAlON), tungsten oxynitride (WON), tantalum oxynitride (TaON), titanium carbonitride (TiCN), or tantalum carbonitride (TaCN). Also, the lower electrode 50 may have a stack structure of any of the above-described materials.

The magnetic memory layer 60 can be disposed on the lower electrode 50. The magnetic memory layer 60 may be electrically connected to the lower electrode 50. The magnetic memory layer 60 may include a lower magnetic layer 62, an upper magnetic layer 64, and a tunnel barrier layer 66 provided therebetween. The lower magnetic layer 62, the upper magnetic layer 64, and the tunnel barrier layer 66 may constitute a magnetic tunnel junction (MTJ) or a spin valve. For example, when the tunnel barrier layer 66 is insulative, the lower magnetic layer 62, the upper magnetic layer 64, and the tunnel barrier layer 66 may provide a magnetic tunnel junction structure. When the tunnel barrier layer 66 is conductive, however, the lower magnetic layer 62, the upper magnetic layer 64, and the tunnel barrier layer 66 may provide a spin valve structure.

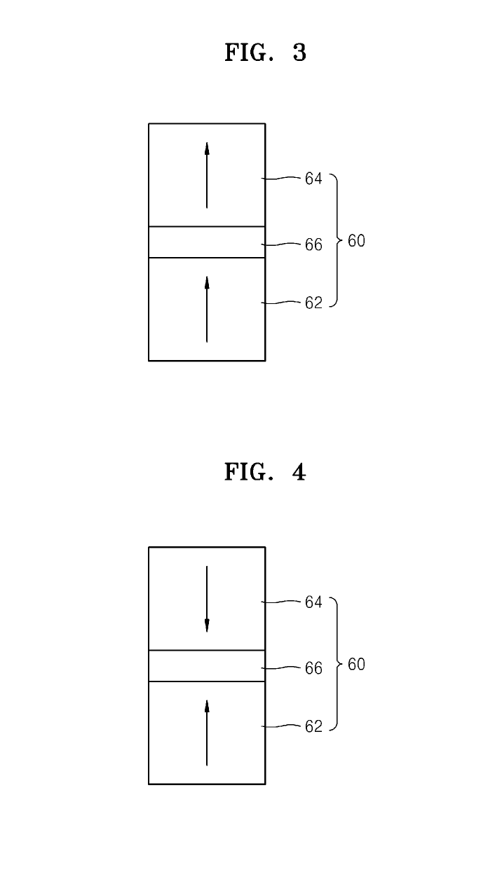

The lower magnetic layer 62 and the upper magnetic layer 64 may each have a perpendicular magnetization direction. That is, the magnetization direction may be perpendicular to the surface of the substrate 10. A memory operating method of the magnetic memory layer 60 having a perpendicular magnetization direction is described below with reference to FIGS. 3 to 6. However, the present inventive concepts are not limited thereto, and it should be understood that embodiments in which the lower and upper magnetic layers 62 and 64 each have a horizontal magnetization direction are also contemplated within the scope of the present inventive concepts.

In operation, the tunnel barrier layer 66 functions to change the magnetization direction of the lower magnetic layer 62 or the upper magnetic layer 64 as electrons are tunnelled through the tunnel barrier layer 66. Thus, the tunnel barrier layer 66 may have a relatively small thickness so that electrons may easily be tunnelled therethrough. In the case of an MTJ structure, the tunnel barrier layer 66 may be insulative and include, for example, oxide, nitride, or oxynitride. The tunnel barrier layer 66 may include, for example, at least one of magnesium oxide, magnesium nitride, magnesium oxynitride, silicon oxide, silicon nitride, silicon oxynitride, silicon carbonate, aluminium oxide, aluminium nitride, aluminium oxynitride, calcium oxide, nickel oxide, hafnium oxide, tantalum oxide, zirconium oxide, and manganese oxide. The tunnel barrier layer 66 may be insulative and alternatively or additionally include, for example, non-magnetic transition metal, and for example, at least one of copper (Cu), gold (Au), tantalum (Ta), silver (Ag), copper pyrithione (CuPt), and copper manganese (CuMn).

The stress-generating layer 70 can be disposed on the magnetic memory layer 60. The stress-generating layer 70 may transfer stress to the tunnel barrier layer 66 of the magnetic memory layer 60. In the present exemplary embodiment, the stress-generating layer 70 can be disposed between the magnetic memory layer 60 and the upper electrode 80.

Applying a voltage between the lower electrode 50 and the upper electrode 80 attempts to change the volume of the stress-generating layer 70. However, since the stress generating layer 70 is surrounded by the third interlayer insulation layer 90, the volume of the stress generating layer 70 cannot be changed, and instead, a stress is generated. The generated stress may be a tensile stress. However, a case in which the generated stress is a compression stress is also contemplated and should be considered as being within the technical scope of the present inventive concepts. The generated tensile stress is transferred to the tunnel barrier layer 66, thus helping to prevent the undesired generation of oxygen vacancies in the tunnel barrier layer 66. The function and operation of the stress-generating layer 70 is described in further detail below with reference to FIG. 7.

To effectively transfer the generated stress to the tunnel barrier layer 66, the stress generating layer 70 may, for instance, be configured and arranged to overlap a substantial portion of the tunnel barrier layer 66, or configured to have a cross-section that is the same as or larger than that of the tunnel barrier layer 66. However, these are exemplary configurations only, and the present inventive concepts are not limited thereto. The stress-generating layer 70 may further be configured having non-magnetic or magnetic characteristics. When the stress-generating layer 70 has non-magnetic characteristics, the stress-generating layer 70 may further perform the function of pinning the magnetization direction of the upper magnetic layer 64.

The stress-generating layer 70 may have piezoelectric deformation characteristics that generate stress as a voltage is applied. The stress-generating layer 70 may include, for example, a ferroelectric material having piezoelectric deformation characteristics. The ferroelectric material may have non-magnetic characteristics. The stress-generating layer 70 may include, for example, a perovskite-based material. The stress-generating layer 70 may include, for example, at least one of lead zirconium titanite (PZT), barium titanyl oxalate (BTO), quartz, AlPO₄, GaPO₄, La₃Ga₅SiO₁₄, SrTiO₃, BiFeO₃, Pb₂KN₅5O₁₅, PbTiO₃, LiTaO₃, NaₓWO₃, KNbO₃, LiNbO₃, Ba₂NaNb₅O₅, ZnO, and AlN.

The stress-generating layer 70 may alternatively have a magnetostrictive characteristic that causes stress to be generated. The stress-generating layer 70 may include, for example, a giant magnetostrictive material (GMM). The GMM may have a [AₓB_{y}]_{z} structural formula, where “A” may be at least one of Gd, Tb, Sm, Dy, and Mo and “B” may be at least one of Fe, Co, and Ni. For example, the stress-generating layer 70 may, for example, comprise a binary alloy such as TbFe₂, DyFe₂, SmFe₂, etc. or a ternary alloy such as TbₓDy₁₋ₓFe_{2-y}. When the stress-generating layer 70 includes a GMM, the stress-generating layer 70 may include a reverse magnetostrictive material that may generate tensile stress according to the application of a voltage.

The stress-generating layer 70 may include a multi-layered superlattice structural material in which heterogeneous materials are stacked in multiple layers, thus permitting stress to be generated. The multi-layered superlattice structural material may have magnetic or non-magnetic characteristics.

The upper electrode 80 can be disposed on the stress-generating layer 70. The magnetic memory layer 60 can be electrically connected to the upper electrode 80. The upper electrode 80 may include metal such as such as aluminium (Al), copper (Cu), tungsten (W), titanium (Ti), or tantalum (Ta), or an alloy such as titanium tungsten (TiW) or titanium aluminium (TiAl), or carbon (C). The upper electrode 80 may alternatively or additionally include titanium nitride (TiN), titanium aluminium nitride (TiAlN), tantalum nitride (TaN), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminium nitride (ZrAlN), molybdenum aluminium nitride (MoAlN), tantalum silicon nitride (TaSiN), tantalum aluminium nitride (TaAlN), titanium oxynitride (TiON), titanium aluminium oxynitride (TiAlON), tungsten oxynitride (WON), tantalum oxynitride (TaON), titanium carbonitride (TiCN), or tantalum carbonitride (TaCN). The upper electrode 80 may have a stack structure of the above-described materials. The lower electrode 50 and the upper electrode 80 may be formed of the same material or different materials.

A fifth contact plug 84 can be disposed on the upper electrode 80. The upper electrode 80 can be electrically connected to the fifth contact plug 84. The fifth contact plug 84 may include, for example, at least one of titanium (Ti), titanium nitride (TiN), tungsten (W), and tungsten nitride (WN), or a stack structure of the above materials.

The lower electrode 50, the magnetic memory layer 60, the upper electrode 80, and the fifth contact plug 84 may be surrounded by the third interlayer insulation layer 90. The third interlayer insulation layer 90 may include oxide, nitride, or oxynitride. The third interlayer insulation layer 90 may include, for example, at least one of silicon oxide, silicon nitride, and silicon oxynitride.

The bit line BL can be disposed on the fifth contact plug 84. The fifth contact plug 84 can be electrically connected to the bit line BL.

As described above, the first to fifth contact plugs 25, 26, 34, 54, and 84, the fifth to third interlayer insulation layers 30, 40, and 90, the lower electrode 50 and the upper electrode 80, and the magnetic memory layer 60, (and other features) may be formed, for example, using a method such as sputtering, chemical vapour deposition (CVD), plasma enhanced CVD (PECVD), or an atomic layer deposition (ALD). The above-described structures may be formed by performing a planarization process using a photolithography method, an etch method, a chemical mechanical polishing (CMP) method or a dry etch method.

FIGS. 3 through 6 are schematic depictions of magnetic memory elements for explaining a method of storing data using a change in a magnetization direction of the magnetic memory layer of FIG. 2;

Referring to FIGS. 3 through 6, when a predetermined voltage is applied to the word line WL of FIG. 2, the gate structure 20 is turned on and the source line SL and the bit line BL are electrically connected via the magnetic memory layer 60. When the direction of current flowing in the magnetic memory layer 60 is changed, a magnetoresistance value of at least one of the lower magnetic layer 62 and the upper magnetic layer 64 included in the magnetic memory layer 60 changes so that the magnetic memory layer 60 may store data “0” or “1”. That is, by changing the magnetization directions of the lower and upper magnetic layers 62 and 64 between states that are parallel and anti-parallel to each other, different data values may be stored.

In FIGS. 3 and 4, the lower magnetic layer 62 is a pinned layer having its magnetization direction pinned in a single direction, and the upper magnetic layer 64 is a free layer in which the magnetization direction can be changed. In this example, the magnetization direction of the lower magnetic layer 62 is pinned in an upward direction. Although not illustrated, a pinning layer for pinning the magnetization direction of the pinned layer may be further provided above or under the pinned layer, and the pinning layer may include an anti-ferromagnetic material.

Referring to FIGS. 2 and 3, when the gate structure 20 is turned on and current flows from the source line SL to the bit line BL, the magnetization tends to be in the upward direction along a magnetization easy axis. Accordingly, the lower and upper magnetic layers 62 and 64 have an upward, parallel magnetization direction, which indicates a low resistance state. Data “0” may be represented by the low resistance state.

Referring to FIGS. 2 and 4, when the gate structure 20 is turned on and current flows from the bit line BL to the source line SL, the magnetization tends to be in the downward direction, contrary to the magnetization easy axis. Since the upper magnetic layer 64 is a free layer, the magnetization direction is changed to the downward direction. However, the lower pinned magnetic layer 62 retains the upward magnetization direction. Accordingly, the lower and upper magnetic layers 62 and 64 have anti-parallel magnetization directions, which results in a high resistance state. Data “1” may be represented by the high resistance state.

When the magnetization direction of the lower magnetic layer 62 is pinned in the downward direction, data may be stored in the opposite manner. That is, when current flows from the source line SL to the bit line BL, data “1” may be stored and, when current flows from the bit line BL to the source line SL, data “0” may be stored.

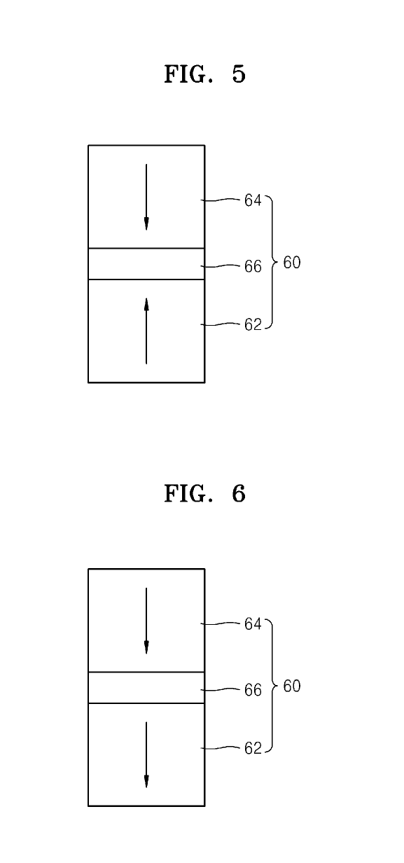

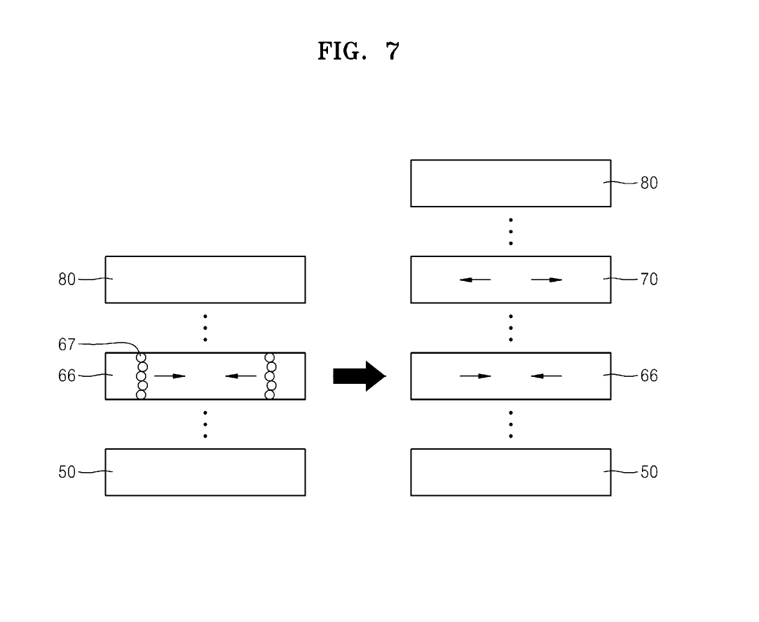

In the embodiments of FIGS. 5 and 6, the lower magnetic layer 62 is a free layer in which the magnetization direction is changed and the upper magnetic layer 64 is a pinned layer in which the magnetization direction is pinned. The magnetization direction of the upper magnetic layer 64 in this embodiment is pinned in the downward direction.

Referring to FIGS. 2 and 5, when the gate structure 20 is turned on and current flows from the source line SL to the bit line BL, the magnetization tends to be in the upward direction along the magnetization easy axis. Since the lower magnetic layer 62 is a free layer, the magnetization direction is changed to the upward direction. However, the upper pinned magnetic layer 64 retains a downward magnetization direction. Accordingly, the lower and upper magnetic layers 62 and 64 have anti-parallel magnetization directions, resulting in a high resistance state. Data “1” may be represented by the high resistance state.

Referring to FIGS. 2 and 6, when the gate structure 20 is turned on and current flows from the bit line BL to the source line SL, the magnetization tends to be in a downward direction. Accordingly, the lower and upper magnetic layers may each 62 and 64 have a downward, parallel magnetization direction, which corresponds to a low resistance state. Data “0” may be represented by this low resistance state.

When the magnetization direction of the upper magnetic layer 64 is pinned in the upward direction, data may be stored in the opposite manner. That is, when current flows from the source line SL to the bit line BL, data “0” may be stored and, when current flows from the bit line BL to the source line SL, data “1” may be stored.

As illustrated in FIGS. 3 through 6, when the lower and upper magnetic layers 62 and 64 store data according to the magnetization direction, a value of the current flowing in the magnetic memory layer 60 is changed. The stored data may be read out by sensing a difference in the current value.

Although FIGS. 3 through 6 illustrate a case in which the lower and upper magnetic layers 62 and 64 have a perpendicular magnetization direction, this is exemplary only, and embodiments in which the lower and upper magnetic layers 62 and 64 each have a horizontal magnetization direction are also contemplated within the technical scope of the present inventive concepts.

FIG. 7 provides a schematic depiction comparing magnetic memory structures without and including a stress generating layer for explaining a function of a stress generating layer according to an exemplary embodiment of the present inventive concepts. In FIG. 7, some layers are omitted which are indicated by a dotted line. The left side of FIG. 7 illustrates a memory structure lacking the stress generating layer 70 does not exist, whereas the right side thereof illustrates includes the stress generating layer 70.

Referring to the left side of FIG. 7, where no stress generating layer is provided, when a voltage over a breakdown voltage of the tunnel barrier layer 66 is applied to the lower and upper electrodes 50 and 80, the chemical combination of oxides in the tunnel barrier layer 66 may be broken and oxygen vacancies 67 may therefore be generated. Oxygen vacancies 67 may form a breakdown percolation path in the tunnel barrier layer 66 so that a tunnelling effect of the tunnel barrier layer 66 may be reduced and the magnetic memory characteristic may be degraded. Since the oxygen vacancies 67 take a part in the volume of the tunnel barrier layer 66, compression stress may be generated in the tunnel barrier layer 66.

In contrast, in the right side of FIG. 7, where a stress generating layer is provided, when a voltage is applied to the stress generating layer 70 by the lower and upper electrodes 50 and 80, stress is generated in the stress generating layer 70. The stress generated in the stress generating layer 70 may be opposite to the type generated in the tunnel barrier layer 66 (e.g., tensile vs. compression stress). The tensile stress generated in the stress generating layer 70 may thereby reduce the compression stress generated in the tunnel barrier layer 66. For example, the tensile stress may reduce or offset the compression stress generated by the oxygen vacancies 67 and may consequently prevent generation of the oxygen vacancies 67. Accordingly, the breakdown voltage of the magnetic memory device 1 may be increased and thus a critical switching current/voltage may be increased. Also, reliability and lifespan of the magnetic memory device 1 may thereby be improved.

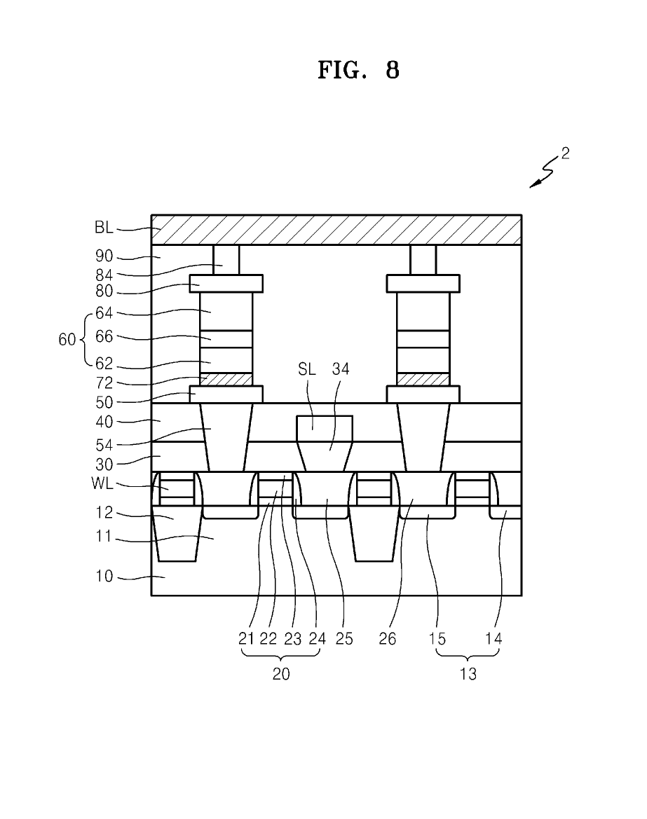

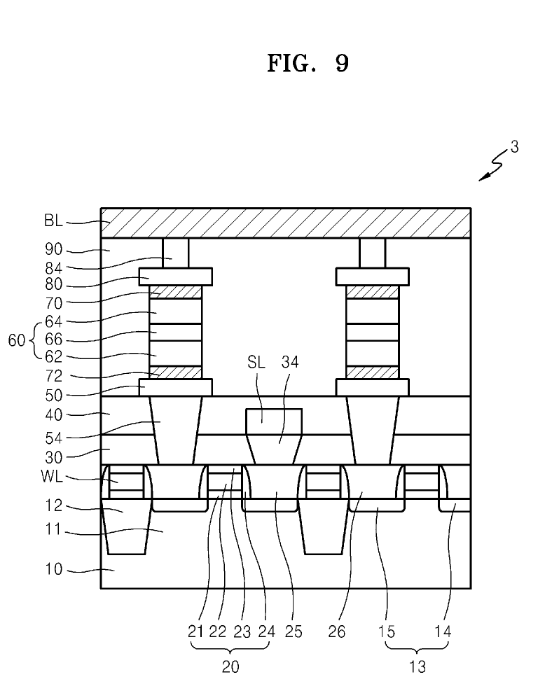

FIGS. 8 and 9 are somewhat schematic cross-sectional views illustrating magnetic memory devices in the area II of the memory array of FIG. 1, according to other exemplary embodiments of the present inventive concepts.

Referring to FIG. 8, a magnetic memory device 2 may include a lower electrode 50, an upper electrode 80, a magnetic memory layer 60 disposed between the lower and upper electrodes 50 and 80, and a stress generating layer 72 configured to transfer stress to the magnetic memory layer 60. More specifically, the stress-generating layer 72 may generate stress and transfer the stress to the tunnel barrier layer 66 of the magnetic memory layer 60. In the present exemplary embodiment, the stress-generating layer 72 can be disposed between the magnetic memory layer 60 and the lower electrode 50. To effectively transfer the generated stress to the tunnel barrier layer 66, the stress generating layer 72 may be configured and disposed so that it overlaps a large portion of the tunnel barrier layer 66 in a vertical direction, or it may be configured to have a cross-sectional area that is the same as or larger than that of the tunnel barrier layer 66. However, this is exemplary only, and the present inventive concepts are not limited thereto. Also, the stress-generating layer 72 may have non-magnetic or magnetic characteristics. When the stress-generating layer 72 has non-magnetic characteristics, the stress-generating layer 72 may perform a function of pinning the magnetization direction of the lower magnetic layer 62.

Referring to FIG. 9, the magnetic memory device 3 may include a lower electrode 50, an upper electrode 80, a magnetic memory layer 60 disposed between the lower and upper electrodes 50 and 80, and stress generating layers 70 and 72 for transferring stresses to the magnetic memory layer 60. The stress generating layers 70 and 72 may generate stress and transfer the stress to the tunnel barrier layer 66 of the magnetic memory layer 60. In the present exemplary embodiment, the stress-generating layer 70 can be disposed between the magnetic memory layer 60 and the lower electrode 50, and the stress-generating layer 72 can be disposed between the magnetic memory layer 60 and the upper electrode 80. To effectively transfer the generated stress to the tunnel barrier layer 66, the stress generating layers 70 and 72 may each be configured and disposed to overlap a large portion of the tunnel barrier layer 66 in a vertical direction, or to have a cross-sectional area that is the same as or larger than that of the tunnel barrier layer 66. However, this is exemplary only, and the present inventive concepts are not limited thereto.

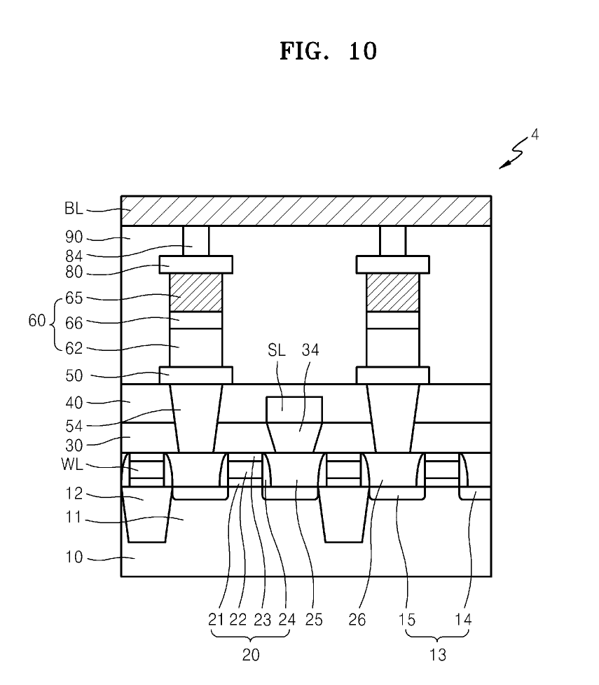

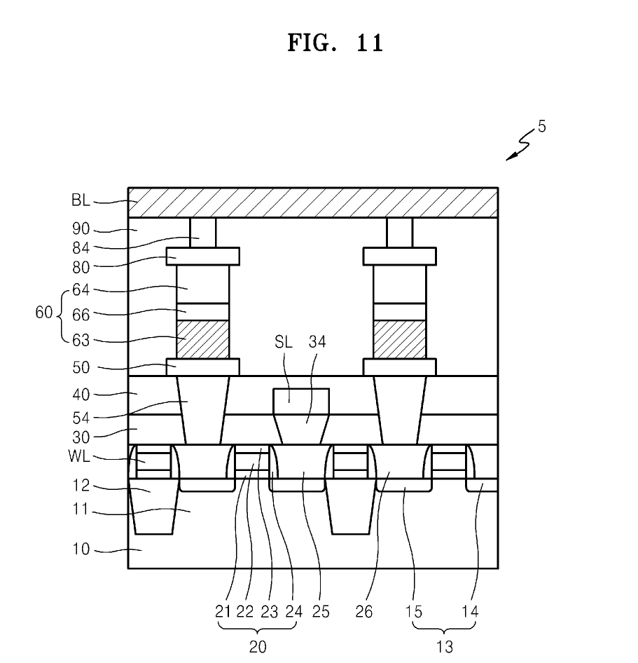

FIGS. 10 to 12 are somewhat schematic cross-sectional views illustrating magnetic memory devices 4, 5, and 6 in the area II of the memory array of FIG. 1, according to other exemplary embodiments of the present inventive concepts.

Referring to FIG. 10, the magnetic memory device 4 may include a lower electrode 50, an upper electrode 80, and a magnetic memory layer 60 disposed between the lower and upper electrodes 50 and 80. The magnetic memory device 4 may further include a stress generating upper magnetic layer 65. The stress generating type upper magnetic layer 65 may be disposed between the tunnel barrier layer 66 and the upper electrode 80 and may, together with the lower magnetic layer 62 and the tunnel barrier layer 66, constitute the magnetic memory layer 60. The stress generating type upper magnetic layer 65 may generate stress and transfer the stress to the tunnel barrier layer 66 of the magnetic memory layer 60. The stress generating type upper magnetic layer 65 may be an integrated single-body structure including both the upper magnetic layer 64 and the stress-generating layer 70 of FIG. 2. The stress generating type upper magnetic layer 65 may include, for example, a magnetostrictive material or a GMM.

Referring to FIG. 11, the magnetic memory device 5 may include a lower electrode 50, an upper electrode 80, and a magnetic memory layer 60 disposed between the lower and upper electrodes 50 and 80. The magnetic memory device 5 may include a stress generating type lower magnetic layer 63. The stress generating type lower magnetic layer 63 may be disposed between the tunnel barrier layer 66 and the lower electrode 50 and may, together with the upper magnetic layer 64 and the tunnel barrier layer 66, constitute the magnetic memory layer 60. Furthermore, the stress generating type lower magnetic layer 63 may generate stress and transfer the stress to the tunnel barrier layer 66 of the magnetic memory layer 60. The stress generating type lower magnetic layer 63 may be an integrated single-body structure including both the lower magnetic layer 62 and the stress-generating layer 72 of FIG. 8. The stress generating type lower magnetic layer 63 may include, for example, a magnetostrictive material or a GMM.

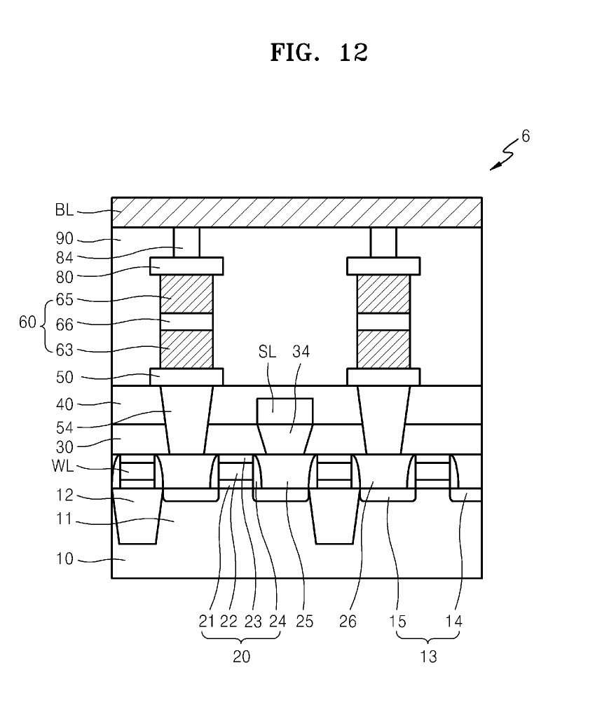

Referring to FIG. 12, the magnetic memory device 6 may include a lower electrode 50, an upper electrode 80, and a magnetic memory layer 60 disposed between the lower and upper electrodes 50 and 80. The magnetic memory device 6 may include a stress generating type upper magnetic layer 65 and a stress generating type lower magnetic layer 63. The stress generating type upper magnetic layer 65 may be disposed between the tunnel barrier layer 66 and the upper electrode 80, and the stress generating type lower magnetic layer 63 may be disposed between the tunnel barrier layer 66 and the lower electrode 50. The stress generating type upper magnetic layer 65, the tunnel barrier layer 66, and the stress generating type lower magnetic layer 63 may constitute the magnetic memory layer 60. Furthermore, the stress generating type upper magnetic layer 65 and the stress generating type lower magnetic layer 63 may each generate stress and transfer the stress to the tunnel barrier layer 66 of the magnetic memory layer 60. The stress generating type upper magnetic layer 65 and the stress generating type lower magnetic layer 63 may each include, for example, a magnetostrictive material or a GMM.

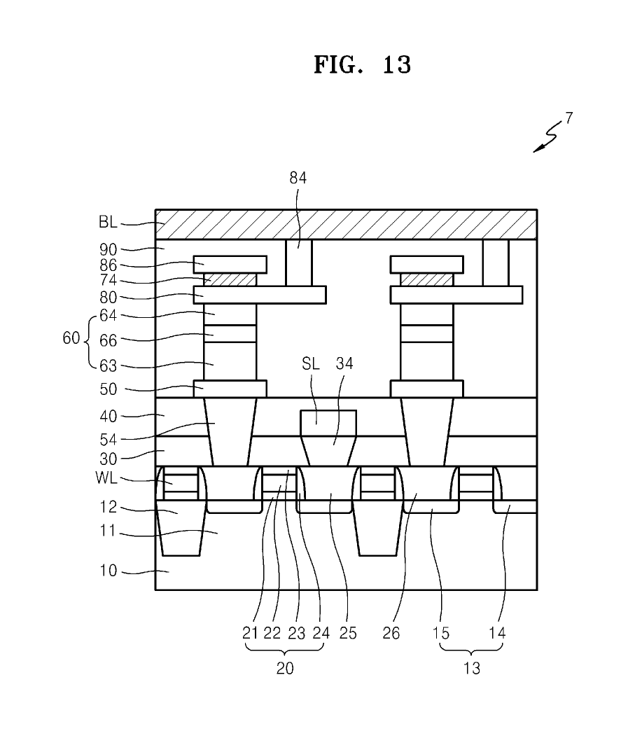

FIGS. 13 to 15 are somewhat schematic cross-sectional views illustrating magnetic memory devices 7, 8, and 9 in the area II of the memory array of FIG. 1, according to other exemplary embodiments of the present inventive concepts.

Referring to FIG. 13, the magnetic memory device 7 may include a lower electrode 50, an upper electrode 80, a magnetic memory layer 60 disposed between the lower and upper electrodes 50 and 80, and a stress generating layer 74 for transferring stress to the magnetic memory layer 60. The magnetic memory device 7 may further include an upper auxiliary electrode 86 disposed at a side of the magnetic memory layer 60 opposite the location of the upper electrode 80. The stress-generating layer 74 may be disposed above the upper electrode 80 and/or may be provided between the upper electrode 80 and the upper auxiliary electrode 86. The stress-generating layer 74 may generate stress according to a voltage applied between the upper electrode 80 and the upper auxiliary electrode 86, and transfer the generated stress to the tunnel barrier layer 66 of the magnetic memory layer 60. To apply a voltage to the stress-generating layer 74, a potential difference may be generated between the upper auxiliary electrode 86 and the upper electrode 80. Accordingly, the upper auxiliary electrode 86 may be electrically connected to the lower electrode 50 or to a separate power line (not shown) that may provide a potential difference from the upper electrode 80.

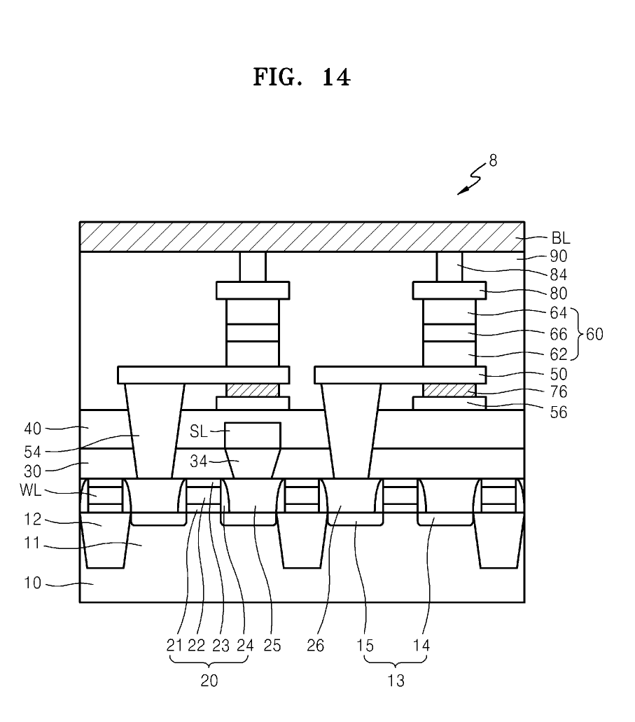

Referring to FIG. 14, the magnetic memory device 8 may include a lower electrode 50, an upper electrode 80, a magnetic memory layer 60 disposed between the lower and upper electrodes 50 and 80, and a stress generating layer 76 for transferring stress to the magnetic memory layer 60. The magnetic memory device 8 may further include a lower auxiliary electrode 56 disposed at a side of the magnetic memory layer 60 opposite the location of the lower electrode 50. The stress-generating layer 76 may be disposed under the lower electrode 50 and/or may be provided between the lower electrode 50 and the lower auxiliary electrode 56. The stress-generating layer 76 may generate stress according to a voltage applied between the lower electrode 50 and the lower auxiliary electrode 56, and transfer the generated stress to the tunnel barrier layer 66 of the magnetic memory layer 60. To apply a voltage to the stress-generating layer 76, a potential difference may be generated between the lower auxiliary electrode 56 and the lower electrode 50. Accordingly, the lower auxiliary electrode 56 may be electrically connected to the upper electrode 80 or to a separate power line (not shown) that may provide a potential difference from the lower electrode 50.

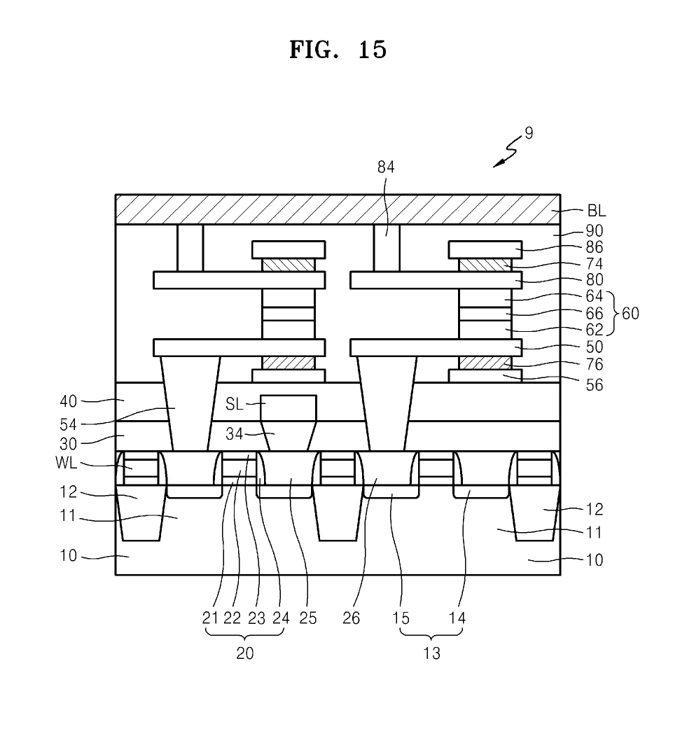

Referring to FIG. 15, the magnetic memory device 9 may include a lower electrode 50, an upper electrode 80, a magnetic memory layer 60 disposed between the lower and upper electrodes 50 and 80, and stress generating layers 74 and 76 for transferring stress to the magnetic memory layer 60. The magnetic memory device 9 may further include an upper auxiliary electrode 86 disposed at a side to the magnetic memory layer 60 opposite the upper electrode 80, and a lower auxiliary electrode 56 disposed at a side of the magnetic memory layer 60 opposite the lower electrode 50. The stress-generating layer 74 may be disposed above the upper electrode 80 and/or may be provided between the upper electrode 80 and the upper auxiliary electrode 86. The stress-generating layer 76 may be disposed under the lower electrode 50 and/or may be provided between the lower electrode 50 and the lower auxiliary electrode 56. The stress-generating layer 74 may generate stress according to a voltage applied between the upper electrode 80 and the upper auxiliary electrode 86, and transfer the generated stress to the tunnel barrier layer 66 of the magnetic memory layer 60. The stress-generating layer 76 may generate stress according to a voltage applied between the lower electrode 50 and the lower auxiliary electrode 56, and transfer the generated stress to the tunnel bather layer 66 of the magnetic memory layer 60. To apply a voltage to the stress-generating layer 74, a potential difference may be generated between the upper auxiliary electrode 86 and the upper electrode 80. Accordingly, the upper auxiliary electrode 86 may be electrically connected to the lower electrode 50 or to a separate power line (not shown) that may provide a potential difference from the upper electrode 80. To apply a voltage to the stress-generating layer 76, a potential difference may be generated between the lower auxiliary electrode 56 and the lower electrode 50. Accordingly, the lower auxiliary electrode 56 may be electrically connected to the upper electrode 80 or to a separate power line (not shown) that may provide a potential difference from the lower electrode 50.

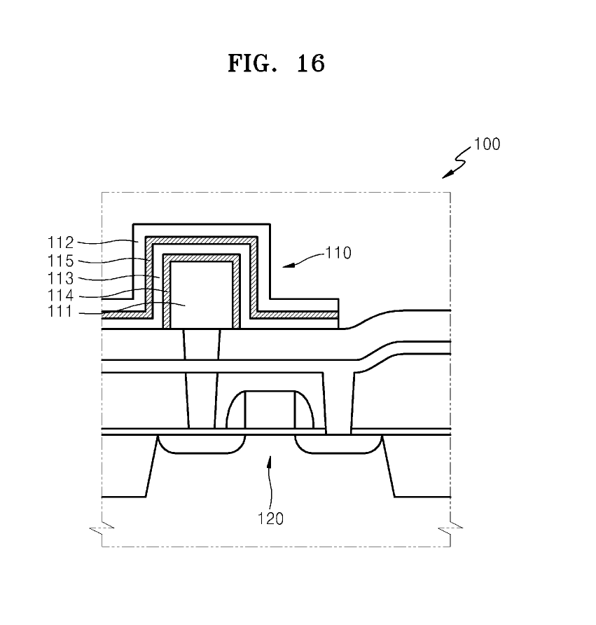

FIG. 16 is a somewhat schematic cross-sectional view illustrating a DRAM device 100 including a stress-generating layer, according to another exemplary embodiment of the present inventive concepts.

Referring to FIG. 16, a DRAM device 100 includes a capacitor element 110 and a transistor element 120. The capacitor element 110 includes a first electrode 111, a second electrode 112, and a dielectric layer 113 provided between the first and second electrodes 111 and 112. A first stress-generating layer 114 may be provided between the first electrode 111 and the dielectric layer 113. Also, a second stress-generating layer 115 may be provided between the second electrode 112 and the dielectric layer 113. When a voltage is applied to the first and second stress generating layers 114 and 115 by the first and second electrodes 111 and 112, the first and second stress generating layers 114 and 115 may each generate stresses and transfer the generated stresses to the dielectric layer 113. Accordingly, the generated stresses may offset a stress created in the dielectric layer as a result of the voltage applied to the dielectric layer 113 by the first and second electrodes 111 and 112. The generated stresses may therefore prevent undesired deformation of the dielectric layer 113. As a result, reliability and lifespan of the DRAM device 100 may be improved.

Accordingly, it should be further understood that a stress-generating layer according to the present inventive concepts may be applied to a variety of electronic devices in order to transfer stress to a dielectric provided between electrodes to prevent deformation or other unwanted effects and improve the reliability and lifespan of those devices.

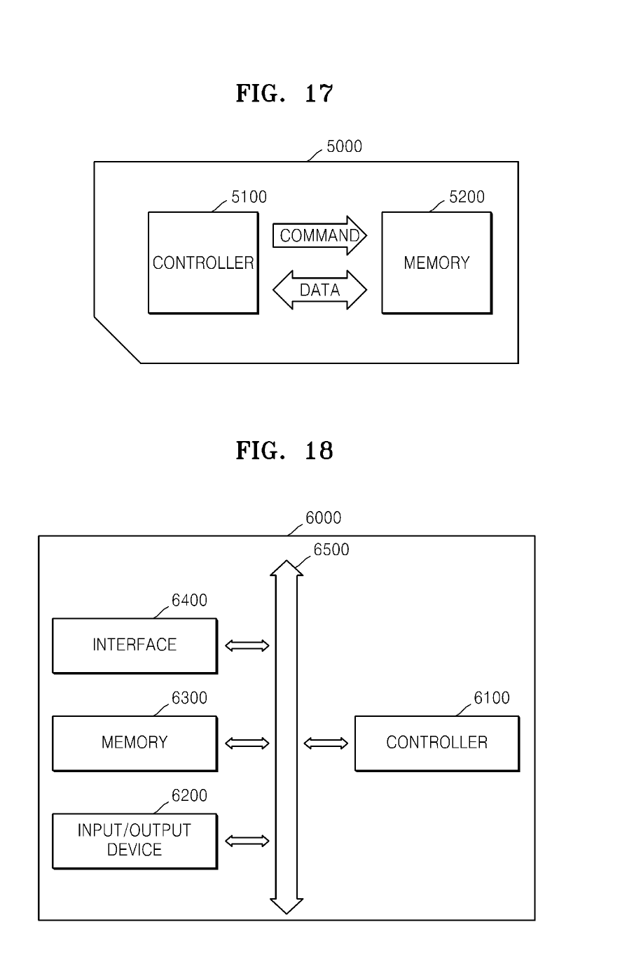

FIG. 17 is a schematic block diagram illustrating a memory card 5000 according to another exemplary embodiment of the present inventive concepts.

Referring to FIG. 17, the memory card 5000 may include a controller 5100 and a memory 5200. The controller 5100 and the memory 5200 may be configured to exchange electric signals. For example, when the controller 5100 issues a command, the memory 5200 may transmit data. The memory 5200 may, for instance, include a phase-change memory device constructed according to any of the above-described exemplary embodiments. The phase-change memory devices according to the above-described exemplary embodiments may be disposed in an architecture memory array (not shown) corresponding to a logic gate design that is well known in the technical field to which the present inventive concepts pertain. A memory array arranged in a plurality of rows and columns may form one or more memory array bank(s) (not shown). The memory 5200 may include the memory array (array) or the memory array bank(s) (not shown). Also, the memory card 5000 may further include a typical row decoder (not shown), a column decoder (not shown), I/O buffers (not shown), and/or a control register (not shown). The memory card 5000 may be used for a variety of memory cards, for example, memory stick cards, smart media (SM) cards, secure digital (SD) cards, mini secure digital (SD) cards, multimedia cards (MMCs), or other such devices.

FIG. 18 is a schematic block diagram schematically illustrating a system 6000 according to a further exemplary embodiment of the present inventive concepts.

Referring to FIG. 18, the system 6000 may include a controller 6100, an input/output device 6200, a memory 6300, and an interface 6400. The system 6000 may be a mobile system or a system for transmitting or receiving information. The mobile system may be a portable digital assistant (PDAs), portable computer, web tablet, wireless phone, mobile phone, digital music player, memory cards, or any other such device. The controller 6100 may execute a program and control the system 6000. The controller 6100 may, for example, be a microprocessor, a digital signal processor, a microcontroller, or any other apparatus similar thereto. The input/output device 6200 can be connected to an external device, such as a personal computer or a network, for example, by using the input/output device 6200, so as to exchange data with the external device. The input/output device 6200 may, for example, be a keypad, a keyboard, or a display. The memory 6300 may store codes and/or data for operating the controller 6100, and/or data processed by the controller. The memory 6300 may include a phase-change memory device according to any of the above-described exemplary embodiments. The interface 6400 may be a data transmission path between the system 6000 and an external apparatus. The controller 6100, the input/output device 6200, the memory 6300, and the interface 6400 may communicate with one another via a bus 6500. For example, the system 6000 may be used for mobile phones, MP3 players, navigations, portable multimedia players (PMPs), solid state disks (SSDs), other household appliances, etc.

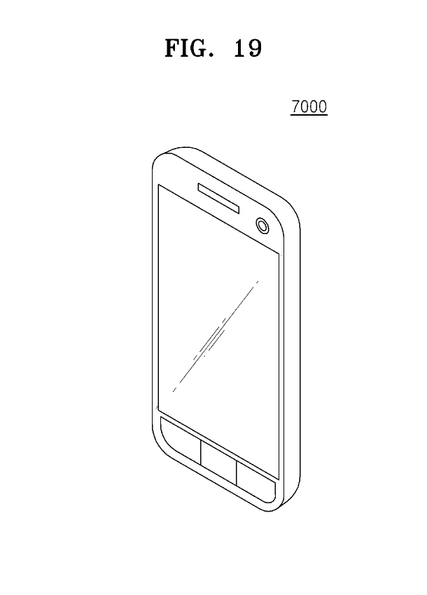

FIG. 19 is a somewhat schematic perspective view of an electronic apparatus 7000 to which a semiconductor device manufactured according to the present inventive concept may be applied.

Referring to FIG. 19, the electronic apparatus 7000 can be a mobile phone in which the electronic system 5000 (see FIG. 17) or 6000 (see FIG. 18) can be applied. Besides a mobile phone, the electronic system 5000 or 6000 may also be applicable to an MP3 player, a navigation device, a portable multimedia player (PMP), a solid state disk (SSD), a vehicle, or other household appliances or the like.

The foregoing description of exemplary embodiments is not to be construed as limiting the present inventive concepts to the particular embodiments described therein. Although exemplary embodiments have been disclosed and described, those of ordinary skill in the art will readily appreciate that many modifications are possible to the exemplary embodiments without materially departing from the novel teachings and advantages thereof. Accordingly, all such modifications are intended to be included within the scope of the claims. The scope of the present inventive concepts is defined by the following claims, with equivalents of the claims to be included therein.

1. A magnetic memory device, comprising:
a magnetic memory layer comprising a plurality of magnetic layers and a tunnel barrier layer provided between the plurality of magnetic layers; and
a stress generating layer configured to apply stress to the tunnel barrier layer.

2. The magnetic memory device of claim 1, further comprising one or more electrodes disposed at opposite sides of the magnetic memory layer,
wherein the stress generating layer generates stress according to a voltage applied by the electrodes.

3. The magnetic memory device of claim 1, wherein the stress generated by the stress generating layer is a type opposite to a type generated by the tunnel barrier layer.

4. The magnetic memory device of claim 3, wherein the generated stress is a tensile stress.

5. The magnetic memory device of claim 1, wherein the stress generating layer has a piezoelectric deformation characteristic.

6. The magnetic memory device of claim 1, wherein the stress generating layer has a magnetostrictive characteristic.

7. The magnetic memory device of claim 2, wherein the stress generating layer is disposed between one of the electrodes and the magnetic memory layer.

8. The magnetic memory device of claim 1, wherein the stress generating layer comprises a plurality of stress generating layers.

9. The magnetic memory device of claim 8, wherein the plurality of stress generating layers are disposed at opposite sides of the magnetic memory layer.

10. The magnetic memory device of claim 1, wherein the stress generating layer forms a single-body structure with at least one of the plurality of magnetic layers.

11. The magnetic memory device of claim 1, wherein the stress generating layer has a magnetic characteristic.

12. The magnetic memory device of claim 1, wherein the stress generating layer comprises at least one of a ferroelectric material, a giant magnetostrictive material, and a multi-layered superlattice structural material.

13. The magnetic memory device of claim 1, wherein the stress generating layer has a cross-sectional area that is the same as or lager than that of the tunnel barrier layer.

14. A magnetic memory device, comprising:
a magnetic memory layer comprising a plurality of magnetic layers and a tunnel barrier layer provided between the plurality of magnetic layers;
a plurality of electrodes disposed at opposite sides of the magnetic memory layer;
an auxiliary electrode disposed at a side of the magnetic memory layer opposite at least one of the plurality of electrodes; and
a stress generating layer disposed between the at least one of the plurality of electrodes and the auxiliary electrode, said stress generating layer configured to generate stress according to a voltage applied between the at least one of the plurality of electrodes and the auxiliary electrode.

15. The magnetic memory device of claim 14, wherein the auxiliary electrode has a potential difference from the at least one of the plurality of electrodes so as to generate the stress in the stress generating layer.

16. The magnetic memory device of claim 14, wherein the at least one of the plurality of electrodes is electrically connected to the auxiliary electrode.

17. A magnetic memory device, comprising:
a magnetic memory layer comprising a plurality of magnetic layers and a tunnel barrier layer provided between the plurality of magnetic layers; and
a stress generating layer comprising a giant magnetostrictive material and configured to apply stress to the tunnel barrier layer,
wherein the giant magnetostrictive material has a [AₓB_{y}]_{z} structural formula, where “A” denotes at least one of Gd, Tb, Sm, Dy, and Mo and “B” denotes at least one of Fe, Co, and Ni.

18. (canceled)

19. (canceled)

20. (canceled)
